(19) United States
(12) Patent Application Publication
(10) Pub. No.: US 2026/0082834 A1
(43) Pub. Date: Mar. 19, 2026

(54) METHOD FOR PRODUCING A SEMICONDUCTOR CHIP HAVING A REFLECTION-REDUCED CHIP SURFACE, AND CHIP SCALE PACKAGE HAVING SUCH A SEMICONDUCTOR CHIP

(71) Applicant: Infineon Technologies AG, Neubiberg (DE)

(72) Inventors: Walter HARTNER, Bad Abbach (DE); Christian GEIßLER, Teugn (DE); Sebastian KRISCH, Regenstauf (DE); Guido WEISS, Pielenhofen (DE)

(21) Appl. No.: 19/307,547

(22) Filed: Aug. 22, 2025

(30) Foreign Application Priority Data
Sep. 13, 2024 (DE) 102024208749.1

(51) Int. Cl. H01L 21/3065; H01L 21/52; H01L 21/78; H10F 77/30; H10F 77/40

(52) U.S. Cl. CPC H10P 50/242; H10F 77/306; H10F 77/413; H10P 54/00; H10W 72/071

(57) ABSTRACT

The present disclosure proposes a method for producing a semiconductor chip having a reflection-reduced chip surface. The method includes the provision of a silicon wafer with a plurality of dies, wherein the silicon wafer and the dies present therein have a reflective silicon surface with a reflectance greater than 50%. The method further includes a step of processing the reflective silicon surfaces in order to produce dies having a reflection-reduced surface with a reflectance equal to or less than 5%. These dies are subsequently singulated in order to obtain semiconductor chips having a reflection-reduced chip surface.

### CROSS-REFERENCE TO RELATED APPLICATION

This application claims priority to Germany Patent Application No. 102024208749.1 filed on Sep. 13, 2024, the content of which is incorporated by reference herein in its entirety.

### TECHNICAL FIELD

The present disclosure relates to the technical field of semiconductor processing. A method for producing a semiconductor chip having a reflection-reduced chip surface is proposed. The semiconductor chips produced using the method disclosed herein find use, in particular, in chip scale packages, since the back side of the semiconductor chip is exposed in chip scale packages.

### SUMMARY

For the production of semiconductor chips, so-called dies are produced in a semiconductor wafer and then singulated. In doing so, the semiconductor wafer is processed in different ways. For example, the surfaces of the semiconductor wafer can be ground or polished, whereby a reflective wafer surface is formed, especially when silicon is used. After singulating the chips, the singulated chips accordingly also have a reflective chip surface.

However, in some technical applications, such as in miniaturized camera modules, such as those currently used in smartphones and the like, reflective surfaces are undesirable, as they influence the light incidence unpredictably and thus may negatively affect the performance of the camera.

To solve this problem, the semiconductor chips are potted with opaque potting materials or packaged in packages that are usually opaque. Naturally, however, these packages increase the footprint, e.g., the base area, of the embedded semiconductor chip.

However, the continuing trend toward miniaturization of electronic components means that conventional packages no longer have enough space for integration into appliances such as smartphones. Therefore, there is a need for developing novel packaging concepts with a smaller footprint.

For example, there are currently chip scale packages on the market whose footprint may be a maximum of 1.2-times larger than the chip contained therein. However, the back side surface of the chip is exposed in chip scale packages, and this in turn leads to the problems mentioned above in the case of reflective chip surfaces.

In order to solve this problem, a method for producing a semiconductor chip having a reflection-reduced chip surface is proposed within the scope of this disclosure. The method includes the provision of a silicon wafer with a plurality of dies, wherein the silicon wafer and the dies present therein have a reflective silicon surface with a reflectance R>50%, The method further includes a step of processing the reflective silicon surfaces in order to produce dies having a reflection-reduced surface with a reflectance R≤5%. These dies are subsequently singulated in order to obtain semiconductor chips having a reflection-reduced chip surface.

A further aspect of the present disclosure relates to a chip scale package having a housing, wherein on one side of the housing a chip surface of a semiconductor chip arranged in the housing is exposed so as to be accessible from the outside, and wherein the exposed chip surface is treated using the method presented herein in order to form a reflection-reduced chip surface having a reflectance R≤5%.

Furthermore, a miniaturized camera module is proposed, having at least one movable optics unit and a chip scale package of the aforementioned type arranged in the immediate vicinity of the movable optics unit. In this case, the chip scale package has at least one linear displacement sensor, which is configured to detect a movement of the movable optics unit.

A further part of this disclosure relates to an electronic handheld device having such a miniaturized camera module.

A person skilled in the art will discern further features and advantages of the implementation upon reading the following detailed description and examining the attached drawings.

### BRIEF DESCRIPTION OF THE DRAWINGS

The present disclosure is shown in an example and non-limiting manner in the illustrations of the attached drawings, in which identical reference numbers refer to similar or identical elements. The elements in the drawings are not necessarily depicted to scale in relation to each other. The features of the various examples shown can be combined, provided that they are not mutually exclusive.

FIG. 1 shows a conventional chip scale package with an exposed reflective chip surface.

FIG. 2 shows a chip scale package according to one implementation.

FIG. 3 shows a schematic block diagram of a method according to the innovative concept disclosed herein.

FIGS. 4A-4C show representative images for illustrating an innovative method for producing a reflection-reduced silicon surface according to one example implementation.

FIGS. 5A-5G show representative images for illustrating an innovative method for producing a reflection-reduced silicon surface according to one example implementation.

FIGS. 6A-6F show representative images for illustrating an innovative method for producing a reflection-reduced silicon surface according to one example implementation.

FIG. 7 shows the structuring of a microlens into a silicon substrate as a constituent part of the innovative method for producing a reflection-reduced silicon surface.

FIGS. 8A-8D show representative images for illustrating an innovative method for producing a reflection-reduced silicon surface according to one example implementation using microlenses.

FIGS. 9A-9F show different microlenses according to example implementations.

FIG. 10 shows a microscopic view of a roughened silicon surface, which has randomly arranged pyramid structures, as an example implementation of an innovative method for producing a reflection-reduced silicon surface.

FIGS. 11A-11C show representative images for illustrating an innovative method for producing a reflection-reduced silicon surface according to one example implementation using a back side protection (BSP) film.

### DETAILED DESCRIPTION

The implementations described here enable the production of a semiconductor chip having a reflection-reduced chip surface. For the purposes of this disclosure, the phrase “reflection reduction” should be understood to mean a reduction in the reflectance R of an otherwise mirroring or reflective surface. The reflectance R refers to the ratio between the reflected and incident intensities as an energy parameter, e.g., in the case of electromagnetic waves (luminous flux). Reflective surfaces have a reflectance of R>50% (e.g., greater than 50%). The reflectance R is thus inversely proportional to the absorptance of a surface. A reflection-reduced surface within the meaning of the present disclosure has a reflectance of R≤5% (e.g., equal to or less than 5%), which corresponds to an absorptance of ≥95% (e.g., equal to or greater than 95%). In some example implementations, however, the reflectance can also be reduced to R≤2% or R≤1% or R≤0.5% or R≤0.05%.

For illustrative purposes only, the innovative concept is described in example fashion below, with reference to the figures, using the example of a semiconductor chip that is configured as a displacement sensor for detecting the movement of a movable optics unit in a miniaturized camera module. However, this example is not limiting, because the innovative method described herein for producing a semiconductor chip having a reflection-reduced chip surface can be used for all types of semiconductor chips that have a reflective chip surface on account of previous processing steps.

These days, many electronic handheld devices, such as smartphones or tablets, have cameras installed. Modern camera modules not only feature optical image stabilization (OIS) but also an autofocus and optical zoom. Each of these functions require displacement sensors to detect the movement of the optics unit (e.g., lens element, lens, etc.) integrated in the camera module. In addition to Hall sensors, magnetoresistive sensors can also be used for this purpose, the latter being preferred due to a better signal-to-noise ratio (SNR).

In semiconductor chips, the sensor system for position detection is integrated in the form of integrated circuits (ICs). For a space-saving arrangement in the respective handheld device, the semiconductor chips are arranged in close proximity to the movable optics unit. For example, in this context at least three sensors are required for optical image stabilization, at least one sensor is required for the autofocus, and at least one sensor is also required for the optical zoom.

This increased number of sensor chips results in a space problem on the circuit board of the handheld device. Therefore, a solution needs to be found to reduce the size of the currently used chip packages. For this purpose, use is currently made of so-called chip scale packages, whose footprint according to the standard may be a maximum of 1.2-times larger than the chip packaged therein. However, the reflective or highly reflective back side surface of the chip is exposed in chip scale packages, and this causes incident light to be scattered unpredictably. This reflected stray light can significantly negatively affect the performance of the camera.

In order to solve this problem, the present disclosure proposes a method for producing a semiconductor chip having a reflection-reduced chip surface. The reflection-reduced chip surface ensures that incident light is no longer reflected undesirably but is largely absorbed. For example, the previously mentioned negative influence of stray light on the optics unit of a camera module can be significantly reduced.

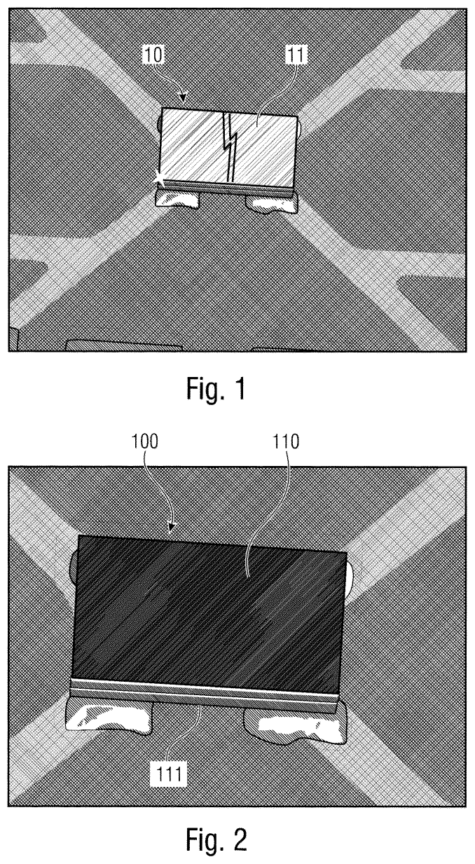

FIG. 1 shows an example of a conventional CSP (CSP: chip scale package) package 10, which is arranged on a component carrier such as a PCB (printed circuit board). In this conventional CSP package 10 (e.g., CSP 10), the back side chip surface 11 is exposed. Due to previous processing steps in the production of the CSP package 10, the chip surface 11 is reflective or highly reflective, e.g., the chip surface 11 has a reflectance R of R>50%.

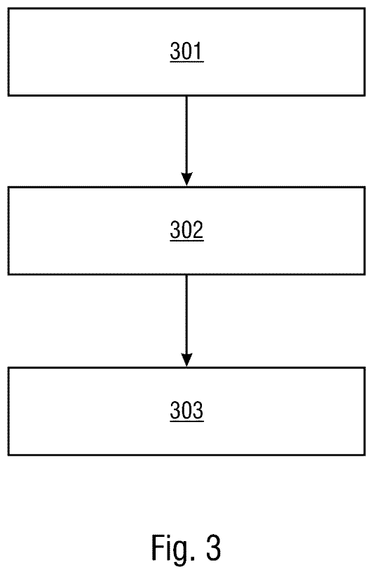

By comparison, FIG. 2 shows an implementation of an innovative CSP package 100 comprising a semiconductor chip having a reflection-reduced chip surface 110. This reflection-reduced chip surface 110 is obtained by the application of the innovative method disclosed herein.

The innovative chip scale package 100 has a housing 111, wherein on one side of the housing 111 the back side chip surface of the semiconductor chip arranged in the housing 111 is exposed so as to be accessible from the outside. This exposed chip surface or chip back side can be treated using the innovative method described in detail below in order to form a reflection-reduced chip surface 110 with a reflectance R≤5%.

The innovative chip scale package 100 can, for example, be integrated into a miniaturized camera module (not explicitly depicted here) with at least one movable optics unit, which is why such a miniaturized camera module is also the subject matter of the present disclosure. In this context, the innovative chip scale package 100 may be arranged in the direct vicinity of the movable optics unit. For example, this lends itself when the chip scale package 100 has at least one linear displacement sensor, which is configured to detect a movement of the movable optics unit. By preference, the linear displacement sensor may be a magnetoresistive sensor. Such a chip scale package 100 having a linear displacement sensor can be used, for example, for optical image stabilization, the autofocus or the optical zoom of the camera module.

Such miniaturized camera modules comprising an innovative chip scale package 100 having a reflection-reduced chip surface 11 can for example be installed in an electronic handheld device, such as a smartphone, a tablet and the like, which is why such an electronic handheld device is also the subject matter of the present disclosure.

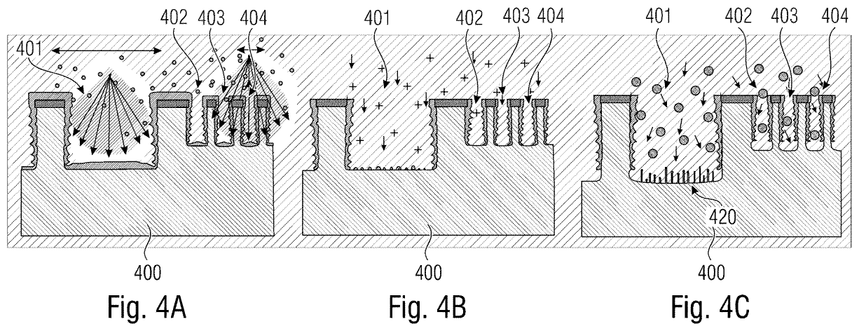

FIG. 3 shows a schematic block diagram of an innovative method for producing such a semiconductor chip having a reflection-reduced chip surface 110. The chronology of process sequence may also be different to the sequence shown.

A silicon wafer with a plurality of dies is provided in block 301, wherein the silicon wafer and the dies present therein have a reflective silicon surface with a reflectance R>50%, This reflective silicon surface can for example be formed during wafer processing, for example by grinding or polishing.

In block 302, the reflective silicon surface is treated according to the innovative concept presented herein in order to produce dies having a reflection-reduced surface with a reflectance R≤5%. Corresponding example implementations are described in detail below.

In block 303, the dies are singulated in order to obtain semiconductor chips having a reflection-reduced chip surface 110, as described previously with reference to FIG. 2.

The innovative treatment of the reflective silicon surface can for example include a modification to the reflective silicon surface. In an alternative to that or in addition, the innovative treatment of the reflective silicon surface may for example include a deposition of one or more layers on the reflective silicon surface.

According to an example implementation, the step of treating the reflective silicon surface may include that carbon nanotubes are produced by epitaxial growth on the reflective silicon surface.

In an alternative to that, it would be conceivable that carbon nanotubes are produced in the silicon surface using deep reactive-ion etching (DRIE). The carbon nanotubes may have a diameter of 0.5 nm to 50 nm.

According to an example implementation, the step of treating the reflective silicon surface may include that so-called black silicon is produced on the silicon surface using deep reactive-ion etching. Black silicon has a needle-shaped surface structure, with the produced needle structures having a length L>10 μm given a diameter D<1 μm, and so the structure shape is also referred to as “silicon grass”, “nanograss”or “reactive-ion etching (RIE) grass”.

Both the carbon nanotubes and the nanograss structures (black silicon) lead to an increase in the surface area. Due to its high aspect ratio, the incident light is “swallowed”, as it were, between the deep structures such that a silicon surface treated in this way has a very low reflectance of below 5%.

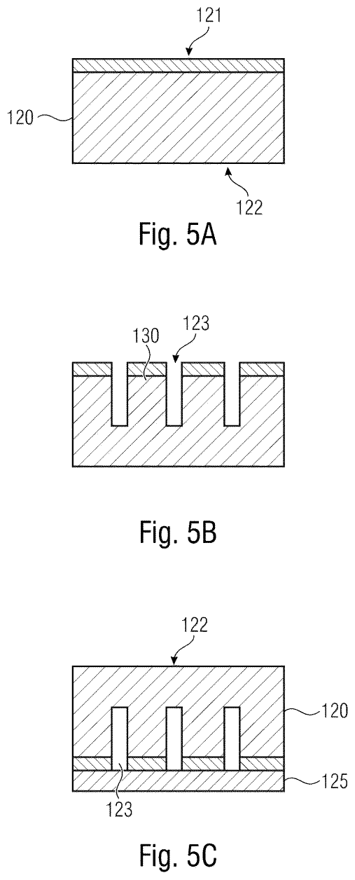

FIGS. 4A to 4C schematically show the production of such nanograss structures by deep reactive-ion etching. In deep reactive-ion etching, one or more cavities 401, 402, 403, 404 can be etched into the surface of a silicon substrate 400. Etching steps and passivation steps alternate in this case.

As evident from FIG. 4A, for example, the cavities 401,. 404 produced thereby may have different aspect ratios. For example, the cavity 401 has a low aspect ratio 410, while the remaining cavities 402, 403, 404 have a larger aspect ratio 420 in comparison therewith. The cavities 401, . . . , 404 can be passivated after each etching step, wherein, depending on the aspect ratio of the cavities 401, . . . , 404, different amounts of passivation material (e.g., SiO2) are deposited at the bottom of the respective cavity 401, . . . , 404.

As evident from FIG. 4B, the passivation can then be removed again, for example in order to subsequently perform a further DRIE etching step. It may be the case that not the entire passivation material is removed, especially in the cavities 401 with a low aspect ratio or in wide cavities 401. Accordingly, very small debris of the passivation material remains at the bottom of cavity 401.

As evident from FIG. 4C, these very small debris mask the ion beam during the subsequent etching process and create structures that are not removed and lead in the subsequent etching and passivation steps to very thin and relatively high silicon pillars 420, which are also referred to as nanoneedles. The process can be set such that one million needles 420 are created in an area of one square millimeter, which is why such a structure is also referred to as nanograss. As mentioned at the outset, a silicon surface treated in this way can also be referred to as black silicon.

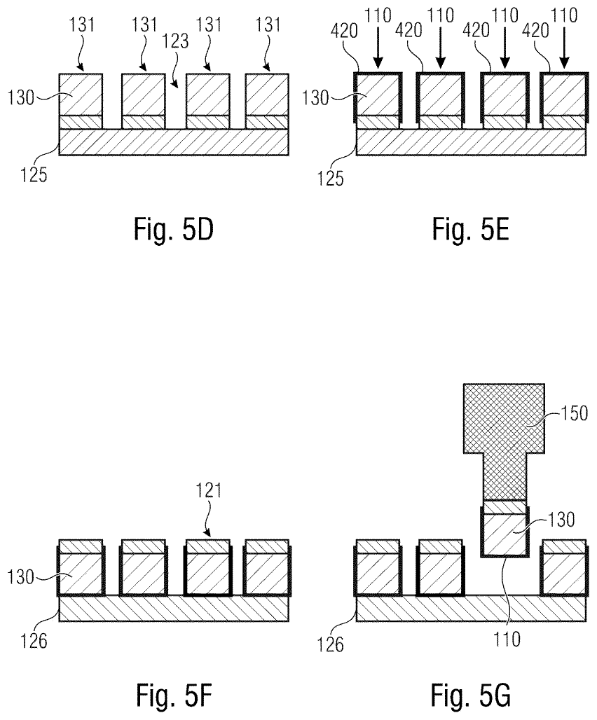

FIGS. 5A to 5G show representative images, using the example of a portion of a schematically illustrated silicon wafer 120, of a conceivable process sequence of an innovative method for producing a semiconductor chip 130 having a reflection-reduced chip surface 110, wherein the individual process steps may also be carried out in a different order to the sequence shown.

In this example, black silicon 420 is produced on the chip surface in order to create the reflection-reduced chip surface 110. FIGS. 5A to 5G show a so-called DBG process sequence (DBG: dicing before grinding), which should be described in detail below.

First of all, FIG. 5A schematically shows a lateral sectional view of a silicon wafer 120. The silicon wafer 120 comprises a first side 121 and an opposing second side 122. The integrated circuits (ICs) are produced on the first side 121, which is why this first side 121 is also referred to as the front side in wafer processing.

Accordingly, the opposing second side 122, which does not contain any ICs, is also referred to as the back side. The wafer portions in which the integrated circuits are produced, and which are later singulated into semiconductor chips, are also referred to as dies at the wafer level.

FIG. 5B shows a further process step. Here, singulation trenches 123 are initially produced around the individual dies 130 on the front side 121 of the silicon wafer 120.

FIG. 5C shows a further process step. Here, the silicon wafer 120 is rotated through 180 degrees and a so-called grinding tape is attached to the front side 121 of the silicon wafer 120.

As evident from FIG. 5D, the exposed back side 122 of the silicon wafer 120 is subsequently ground back to the singulation trenches 123 in order to separate the dies 130 thereby. Looking forward to FIG. 5G, it is evident that the individual dies 130 can then be broken out such that a single semiconductor chip 130 is obtained. The terms die and chip can be used synonymously here.

As a result of grinding back the silicon wafer 120, as discussed with reference to FIG. 5D, the silicon wafer 120 and the dies 130 contained therein obtain a reflective silicon surface 131. Accordingly, the semiconductor chips 130 to be singulated subsequently also have a reflective chip surface at first, because the chip back side still corresponds to the ground-back wafer back side 122 in this case.

FIG. 5E shows a further process step. In this case, the reflective chip surfaces 131 are treated using the innovative method disclosed herein in order to produce a reflection-reduced chip surface 110. For this purpose, for example, the above-described black silicon 420 can be produced on the initially still reflective chip surfaces 131. In doing so, the black silicon 420 may completely cover the reflective chip surfaces 131 such that reflection-reduced chip surfaces 110 are formed. Optionally, the black silicon 420 may also cover the vertical chip edges within the singulation trenches 123, as shown in FIGS. 5E to 5G by way of example.

In an alternative to producing the black silicon 420 or in addition, however, the initially still reflective chip surfaces 131 may also be treated according to all other implementations described herein in order to reduce the reflectance of the initially still reflective chip surfaces 131 and accordingly produce a reflection-reduced chip surface 110. These further implementations for reducing the reflectance of the chip surface will be described in more detail with reference to the following figures.

FIG. 5F shows a further process step. Here, the grinding tape 125 was removed from the front side 121 of the dies 130, and a so-called dicing tape 126 was mounted on the treated, e.g., reflection-reduced, back side 122 of the dies 130. The dies 130 can again be rotated through 180 degrees in the process.

FIG. 5G shows a further process step. Here, the individual dies or semiconductor chips 130 are removed; this can be implemented using a so-called pick & place tool, for example. As a result, a single semiconductor chip 130 having a reflection-reduced chip surface 110 is obtained. As just described, the reflection-reduced chip surface 110 may the chip back side 122, wherein the ICs and bond surfaces can be formed on the opposite front side 121.

The implementation of the present innovation shown in FIGS. 5A to 5G is a so-called DBG process sequence (DBG: dicing before grinding). This is characterized, inter alia, by the fact that the step of producing the black silicon 420 in the process sequence takes place in time after the production of the singulation trenches 123 and after grinding back.

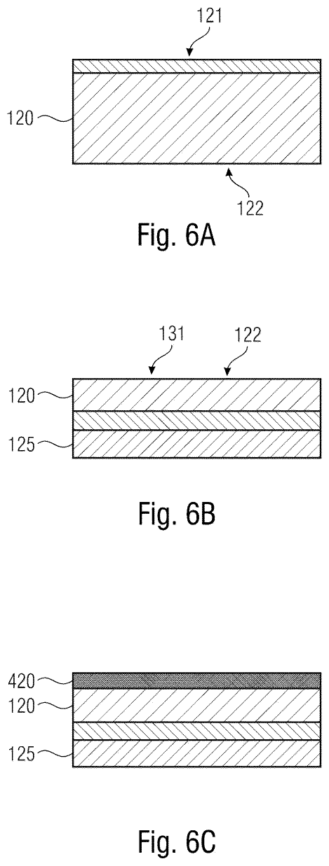

FIGS. 6A to 6F show an alternative example implementation thereto. In this case, the black silicon is produced in a conventional dicing process sequence, wherein the back side 122 of the silicon wafer 120 is ground back first, and the black silicon 420 is produced only then in the ground-back back side 122. In this case, the semiconductor chips 130 are singulated chronologically after the production of the black silicon 420 in the process sequence.

First of all, FIG. 6A schematically shows a lateral sectional view of a silicon wafer 120. The silicon wafer 120 comprises a first side 121 and an opposing second side 122. The integrated circuits are produced on the first side 121, which is why this first side 121 is also referred to as the front side in wafer processing.

Accordingly, the opposing second side 122 is also referred to as the back side. The portions in which the integrated circuits are produced, and which are later singulated into semiconductor chips, are also referred to as dies.

FIG. 6B shows a further process step. Here, the silicon wafer 120 is rotated through 180 degrees and a grinding tape 125 is attached to the front side 121 of the silicon wafer 120. The exposed back side 122 of the silicon wafer 120 is then ground back. By grinding back the silicon wafer 120, the second, ground-back back side 122 of the silicon wafer 120 formed in the process initially receives a reflective silicon surface 131. Looking forward to FIG. 6F, it should be mentioned here that the ground-back back side 122 of the silicon wafer 120 later forms the back side of the semiconductor chip 130 to be produced, wherein the silicon surface 131 of the silicon wafer 120 still reflective at this time subsequently forms the chip back side or chip surface.

FIG. 6C shows a further process step. In this case, the reflective silicon surface 131 of the ground-back back side 122 of the silicon wafer 120 is treated using the innovative method disclosed herein in order to obtain a ground-back back side 122 having a reflection-reduced surface such that a semiconductor chip having a reflection-reduced chip surface 110 can be singulated at a later stage (see FIG. 6F). For this purpose, for example, the above-described black silicon 420 can be produced on the initially still reflective silicon surface 131 of the ground-back back side 122 of the silicon wafer 120. In this case, the black silicon 420 may completely cover the reflective silicon surface 131 of the ground-back back side 122 of the silicon wafer 120.

In an alternative to producing the black silicon 420 or in addition, however, the ground-back reflective silicon surface 131 of the silicon wafer 120 may also be treated according to all other implementations described herein in order to reduce the reflectance of the initially still reflective silicon surfaces 131 and accordingly produce a reflection-reduced chip surface 110 in the singulated semiconductor chips 130. These further implementations for reducing the reflectance of the chip surface will be described in more detail with reference to the following figures.

FIG. 6D shows a further process step. Here, the grinding tape 125 was removed from the front side 121 of the dies 130, and a so-called dicing tape 126 was mounted on the ground-back and treated, e.g., reflection-reduced, back side 122 of the dies 130. The dies 130 can again be rotated through 180 degrees in the process.

As evident from FIG. 6E, singulation trenches 123 are then produced in the front side 121 of the silicon wafer 120 in order to obtain individual dies 130.

FIG. 6F shows a further process step in which the individual dies are broken out such that individual semiconductor chips 130 are obtained. The terms die and chip can be used synonymously here. In this case, the individual dies or semiconductor chips 130 may be removed using a pick & place tool, for example. As a result, a single semiconductor chip 130 having a reflection-reduced chip surface 110 is obtained. As just described, the reflection-reduced chip surface 110 may the chip back side 122, wherein the ICs and bond surfaces can be formed on the opposite front side 121.

With reference to the following figures, the intention is to describe further example implementations, with the aid of which it is possible to reduce the reflectance of the reflective silicon surface 131 of the silicon substrate 120 and the dies contained therein. As mentioned previously, all implementations described herein for reducing the reflectance of the reflective silicon surface 131 are compatible with the processes discussed with reference to FIGS. 5A to 6F.

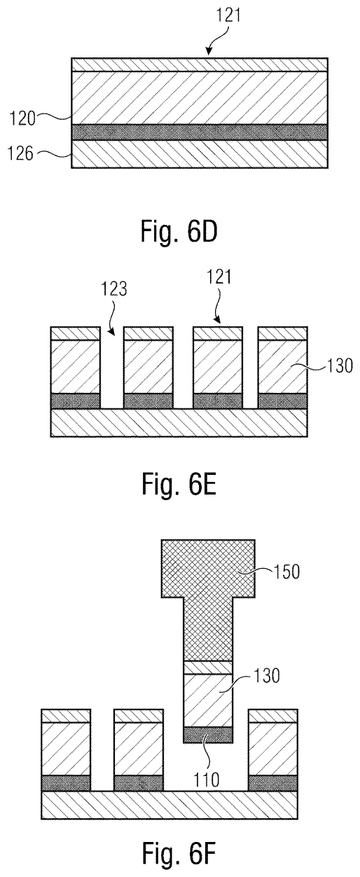

FIG. 7 shows an innovative way of reducing the reflectance of the reflective silicon surface 131 by structuring microlenses 200 into the silicon surface 131 in order to refract incident light. In this context, the microlenses 200 may have different geometric shapes.

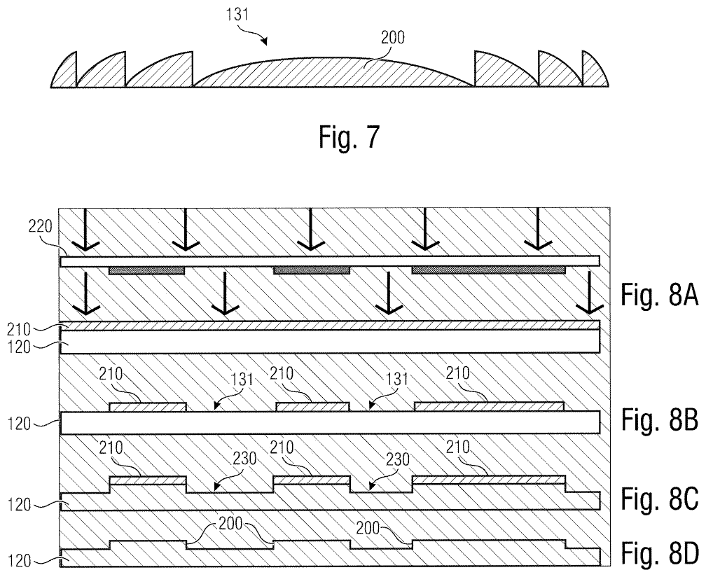

FIGS. 8A to 8D show an option for structuring microlenses 200 in the reflective silicon surface 131. As evident from FIG. 8A, a photoresist layer 210 can be initially applied to the reflective silicon surface 131, which is exposed with a photomask 220.

FIG. 8B shows the structured photoresist layer 210 created post exposure.

FIG. 8C shows a further process step in which the silicon substrate 120 is etched in order to create cavities in the regions of the silicon substrate 120 not covered by the structured photoresist layer 210.

As evident from FIG. 8D, the photoresistive layer 210 is subsequently removed. The substrate material that has remained standing between the cavities 230 produced forms the aforementioned microlenses 200.

Alternatively, however, the microlenses 200 may also be produced by additive methods, by virtue of suitable lens material (e.g., polymers) being applied to the reflective silicon surface 131, for example using inkjet printing.

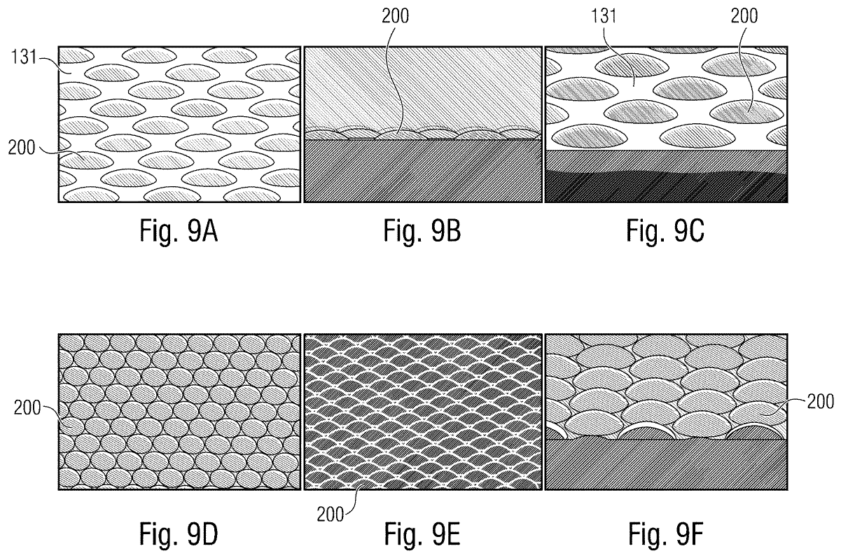

By way of example, FIGS. 9A to 9F depict microlenses 200 that were produced according to the method described herein on a reflective silicon surface 131. The microlenses 200 shown in FIGS. 9A to 9F have different pitches (relative distances from each other).

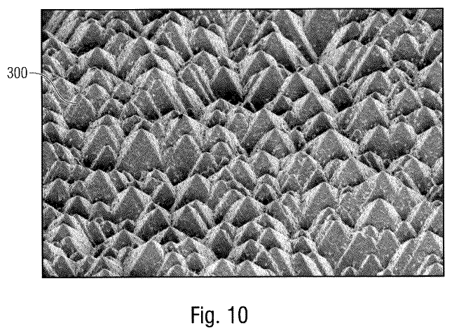

FIG. 10 shows another implementation for reducing the reflectance of the silicon surface 131. In this case, the innovative method involves a step in which the silicon surface 131 is roughened in order to refract incident light. As shown here by way of example, the step of roughening the silicon surface 131 may include randomly distributed pyramid structures being structured into the silicon surface 131. For example, this may be implemented using potassium hydroxide (KOH) wet etching, laser structuring or mechanical abrasion, e.g., using coarse grinding wheels.

A further implementation of the innovative method disclosed herein provides that the step of processing the reflective silicon surface 131 includes an anti-reflective coating being deposited on the silicon surface 131 in order to reduce the reflectance of the silicon surface 131.

The anti-reflective coating can be deposited by using sputtering, chemical vapor deposition or vapor deposition or using atomic layer deposition. The anti-reflective coating may be deposited in alternative to all implementations described herein for reducing the reflectance of the silicon surface 131 or in addition.

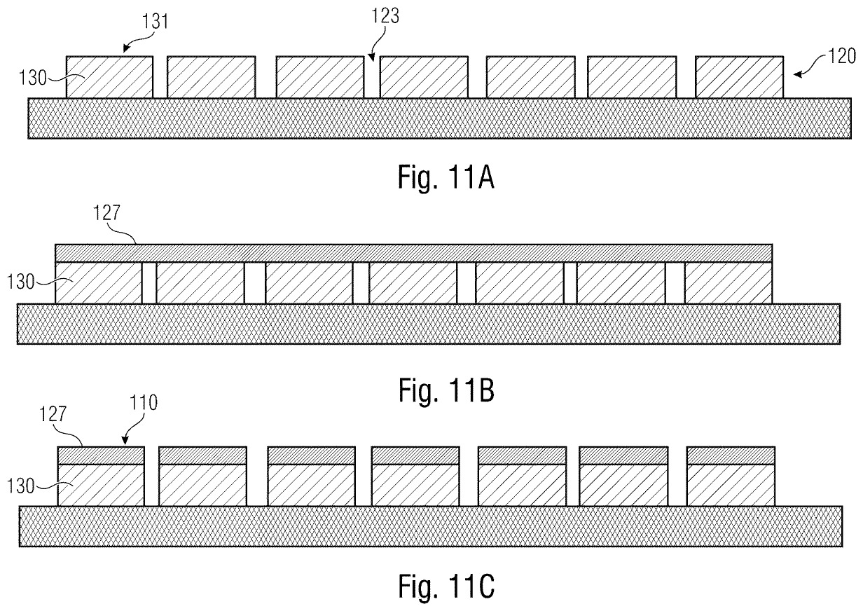

FIGS. 11A to 11C show another example implementation of the method disclosed herein for producing semiconductor chips 130 having a reflection-reduced chip surface 110.

FIG. 11A initially shows a silicon wafer 120 containing a plurality of dies 130 arranged side by side with, initially, a silicon surface 131 that is still reflective, for example as described with reference to FIGS. 5A to 6F.

As evident from FIG. 11B, the step of processing the reflective silicon surface 131 in this implementation may include that the silicon surface 131 is covered with a reflection-reduced BSP film 127 (BSP: back side protection).

FIG. 11C shows the dies after singulation, whereby several individual semiconductor chips 130 each having a reflection-reduced chip surface 110 are formed. In this case, the BSP film 127 may be applied in a dicing before grinding process sequence, wherein singulation trenches 123 (FIG. 11A) are initially produced around the individual dies 130 in the silicon wafer 120 and the back side of the silicon wafer 120 is subsequently ground back side to the singulation trenches 123 in order to singulate the dies 130, in a manner substantially analogous to what was described previously with reference to FIGS. 5A to 5G.

In this case, the step of applying the BSP film 127 in the process sequence takes place in time after the production of the singulation trenches 123 and after grinding back. The BSP film 127 arranged over the singulation trenches 123 is subsequently severed using a laser beam.

In both the process sequence shown with reference to FIGS. 5A to 6F and the process sequence shown with reference to FIGS. 11A to 11C, it is conceivable that the step of processing the reflective silicon surface 131 includes that the singulation trenches 123 are initially produced around the individual dies 130 in the silicon wafer 120, and the singulation trenches 123 are subsequently filled. This also allows the reflectance of the vertical side walls of the semiconductor chips 130 to be reduced.

For example, the singulation trenches 123 may be filled using spray coating, spin coating, deposition of photosensitive epoxy material or lamination with subsequent laser separation.

The semiconductor chips 130 having a reflection-reduced chip surface 110 that are producible using the method presented herein may subsequently be packaged in a chip housing 100 such that the reflection-reduced chip surface 110 of the packaged semiconductor chip 130 is exposed so as to be accessible from the outside. By preference, this may be a chip scale package 100, for example as shown in FIG. 2. A chip scale package 100 offers the smallest package form available on the market today. As a result, a plurality of innovative semiconductor chips 130 can be accommodated in the smallest space, especially in surroundings where reflectance is undesirable, for example in miniaturized camera modules.

The method disclosed herein thus offers an option for reducing the reflectance of reflective silicon surfaces 131. In line with the innovation, this may be implemented by a treatment/modification of the silicon surface 131, and/or a deposition of additional layers on the silicon surface 131.

For example, treatment/modification of the silicon surface 131 may be implemented using: black silicon 420, and/or producing microlenses 200, and/or roughening the silicon surface 131.

For example, deposition of the additional layers on the silicon surface 131 may be implemented using: depositing anti-reflective layers (ARC: anti-reflective coating), and/or filling the singulation trenches 123, and/or applying a reflection-reduced BSP film 127.

In line with the innovation, the previously reflective silicon surface 131, which has a reflectance R>50%, is thus reflection-reduced, and so it subsequently has a reflectance R≤5%.

It should be pointed out that the description and the drawings only illustrate the principles of the proposed methods and devices. A person skilled in the art will be capable of implementing different arrangements which, although they are not expressly described or shown here, embody the principles of the implementation and are contained within the scope thereof. In addition, all examples and implementations outlined in the present document are intended fundamentally and expressly for explanatory purposes only, in order to help the reader understand the principles of the proposed processes and devices. In addition, all statements in this document that describe principles, aspects and implementations of the implementation and specific examples thereof are also intended to encompass their equivalents.

### ASPECTS

The following provides an overview of some Aspects of the present disclosure:

Aspect 1: A method for producing a semiconductor chip having a reflection-reduced chip surface, wherein the method comprises: providing a silicon wafer with a plurality of dies, wherein the silicon wafer has a reflective silicon surface with a reflectance >50; processing the reflective silicon surface to produce dies having a reflection-reduced surface with a reflectance ≤5%; and singulating the dies in order to obtain semiconductor chips having a reflection-reduced chip surface.

Aspect 2: The method as recited in Aspect 1, further comprising: packaging at least one of the semiconductor chips having a reflection-reduced chip surface in a chip housing such that the reflection-reduced chip surface of the at least one semiconductor chip is exposed so as to be accessible from an outside of the chip housing.

Aspect 3: The method as recited in Aspect 2, the chip housing is configured as a chip scale package.

Aspect 4: The method as claimed in any of Aspects 1-3, wherein the step of processing the reflective silicon surface includes producing carbon nanotubes by epitaxial growth on the reflective silicon surface in order to reduce the reflectance of the silicon surface.

Aspect 5: The method as claimed in any of Aspects 1-4, wherein the step of processing the reflective silicon surface includes producing black silicon on the silicon surface using deep reactive-ion etching in order to reduce the reflectance of the silicon surface.

Aspect 6: The method as recited in Aspect 5, wherein the black silicon is produced in a dicing before grinding process sequence, wherein singulation trenches are first produced around the dies in the silicon wafer, and then a back side of the silicon wafer is ground back to the singulation trenches in order to singulate the dies, and wherein the step of producing the black silicon in the process sequence takes place at a time after the production of the singulation trenches and after grinding back.

Aspect 7: The method as recited in Aspect 5, wherein the black silicon is produced in a dicing process sequence, wherein a back side of the silicon wafer is ground back first, and the black silicon is produced only then in a ground-back back side, and wherein in the process sequence, singulation of the semiconductor chips takes place in time after the black silicon has been produced.

Aspect 8: The method as claimed in any of Aspects 1-7, wherein the step of processing the reflective silicon surface includes structuring microlenses into the silicon surface in order to refract incident light and thus reduce the reflectance of the silicon surface.

Aspect 9: The method as claimed in any of Aspects 1-8, wherein the step of processing the reflective silicon surface includes roughening the silicon surface in order to refract incident light and thus reduce the reflectance of the silicon surface.

Aspect 10: The method as recited in Aspect 9, wherein the step of roughening the reflective silicon surface includes structuring randomly distributed pyramid structures into the silicon surface in order to reduce the reflectance of the silicon surface.

Aspect 11: The method as recited in Aspect 9, wherein the reflective silicon surface are roughening using at least one of the following processes: potassium hydroxide (KOH) wet etching, laser structuring, or mechanical abrasion.

Aspect 12: The method as claimed in any of Aspects 1-11, wherein the step of processing the reflective silicon surface includes depositing an anti-reflective coating on the silicon surface in order to reduce the reflectance of the silicon surface.

Aspect 13: The method as recited in Aspect 12, wherein the anti-reflective coating is deposited using at least one of the following processes: sputtering, chemical vapor deposition, vapor deposition, or atomic layer deposition.

Aspect 14: The method as claimed in any of Aspects 1-13, wherein the step of processing the reflective silicon surface includes first producing singulation trenches around the dies in the silicon wafer, and then filling the singulation trenches to reduce the reflectance of vertical side walls of the dies.

Aspect 15: The method as recited in Aspect 14, wherein the singulation trenches are filled using at least one of the following processes: spray coating, spin coating, deposition of photosensitive epoxy material, or lamination with subsequent laser singulation.

Aspect 16: The method as claimed in any of Aspects 1-15, wherein the step of processing the reflective silicon surface includes covering the silicon surface with a reflection-reduced back side protection (BSP) film.

Aspect 17: The method as recited in Aspect 16, wherein the BSP film is applied in a dicing before grinding process sequence, wherein singulation trenches are first produced around the dies in the silicon wafer, and then the back side of the silicon wafer is ground back to the singulation trenches in order to singulate the dies, and wherein the step of applying the BSP film in the process sequence takes place in time after the production of the singulation trenches and after grinding back, and wherein the BSP film arranged over the singulation trenches is subsequently severed using a laser beam.

Aspect 18: A chip scale package, comprising: a housing, wherein on one side of the housing a chip surface of a semiconductor chip arranged in the housing is exposed so as to be accessible from an outside of the housing, wherein the chip surface is a reflection-reduced chip surface having a reflectance ≤5%.

Aspect 19: A miniaturized camera module, comprising: a movable optics unit; and a chip scale package arranged in an immediate vicinity of the movable optics unit, the chip scale package comprising: a housing; a semiconductor chip arranged in the housing, wherein, on one side of the housing, a chip surface of the semiconductor chip is exposed so as to be accessible from an outside, wherein the chip surface is a reflection-reduced chip surface having a reflectance ≤5%; and at least one linear displacement sensor configured to detect a movement of the movable optics unit.

Aspect 20: The miniaturized camera module as recited in Aspect 19, wherein the at least one linear displacement sensor is a magnetoresistive sensor.

Aspect 21:

Aspect 22: A system configured to perform one or more operations recited in one or more of Aspects 1-21.

Aspect 23: An apparatus comprising means for performing one or more operations recited in one or more of Aspects 1-21.

1. A method for producing a semiconductor chip having a reflection-reduced chip surface, wherein the method comprises:
providing a silicon wafer with a plurality of dies, wherein the silicon wafer has a reflective silicon surface with a reflectance >50;
processing the reflective silicon surface to produce dies having a reflection-reduced surface with a reflectance ≤5%; and
singulating the dies in order to obtain semiconductor chips having a reflection-reduced chip surface.

2. The method as claimed in claim 1, further comprising:
packaging at least one of the semiconductor chips having a reflection-reduced chip surface in a chip housing such that the reflection-reduced chip surface of the at least one semiconductor chip is exposed so as to be accessible from an outside of the chip housing.

3. The method as claimed in claim 2, the chip housing is configured as a chip scale package.

4. The method as claimed in claim 1, wherein the step of processing the reflective silicon surface includes producing carbon nanotubes by epitaxial growth on the reflective silicon surface in order to reduce the reflectance of the silicon surface.

5. The method as claimed in claim 1, wherein the step of processing the reflective silicon surface includes producing black silicon on the silicon surface using deep reactive-ion etching in order to reduce the reflectance of the silicon surface.

6. The method as claimed in claim 5, wherein the black silicon is produced in a dicing before grinding process sequence, wherein singulation trenches are first produced around the dies in the silicon wafer, and then a back side of the silicon wafer is ground back to the singulation trenches in order to singulate the dies, and
wherein the step of producing the black silicon in the process sequence takes place at a time after the production of the singulation trenches and after grinding back.

7. The method as claimed in claim 5, wherein the black silicon is produced dicing process sequence, wherein a back side of the silicon wafer is ground back first, and the black silicon is produced only then in a ground-back back side, and
wherein in the process sequence, singulation of the semiconductor chips takes place in time after the black silicon has been produced.

8. The method as claimed in claim 1, wherein the step of processing the reflective silicon surface includes structuring microlenses into the silicon surface in order to refract incident light and thus reduce the reflectance of the silicon surface.

9. The method as claimed in claim 1, wherein the step of processing the reflective silicon surface includes roughening the silicon surface in order to refract incident light and thus reduce the reflectance of the silicon surface.

10. The method as claimed in claim 9, wherein the step of roughening the reflective silicon surface includes structuring randomly distributed pyramid structures into the silicon surface in order to reduce the reflectance of the silicon surface.

11. The method as claimed in claim 9, wherein the reflective silicon surface are roughening using at least one of the following processes:
potassium hydroxide (KOH) wet etching,
laser structuring, or
mechanical abrasion.

12. The method as claimed in claim 1, wherein the step of processing the reflective silicon surface includes depositing an anti-reflective coating on the silicon surface in order to reduce the reflectance of the silicon surface.

13. The method as claimed in claim 12, wherein the anti-reflective coating is deposited using at least one of the following processes:
sputtering,
chemical vapor deposition,
vapor deposition, or
atomic layer deposition.

14. The method as claimed in claim 1, wherein the step of processing the reflective silicon surface includes first producing singulation trenches around the dies in the silicon wafer, and then filling the singulation trenches to reduce the reflectance of vertical side walls of the dies.

15. The method as claimed in claim 14, wherein the singulation trenches are filled using at least one of the following processes:
spray coating,
spin coating,
deposition of photosensitive epoxy material, or
lamination with subsequent laser singulation.

16. The method as claimed in claim 1, wherein the step of processing the reflective silicon surface includes covering the silicon surface with a reflection-reduced back side protection (BSP) film

17. The method as claimed in claim 16, wherein the BSP film is applied in a dicing before grinding process sequence, wherein singulation trenches are first produced around the dies in the silicon wafer, and then the back side of the silicon wafer is ground back to the singulation trenches in order to singulate the dies, and
wherein the step of applying the BSP film in the process sequence takes place in time after the production of the singulation trenches and after grinding back, and
wherein the BSP film arranged over the singulation trenches is subsequently severed using a laser beam.

18. A chip scale package comprising:
a housing, wherein on one side of the housing a chip surface of a semiconductor chip arranged in the housing is exposed so as to be accessible from an outside of the housing,
wherein the chip surface is a reflection-reduced chip surface having a reflectance ≤5%.

19. A miniaturized camera module-having, comprising:
a movable optics unit; and
a chip scale package arranged in an immediate vicinity of the movable optics unit, the chip scale package comprising:
a housing:
a semiconductor chip arranged in the housing,
wherein, on one side of the housing, a chip surface of the semiconductor chip is exposed so as to be accessible from an outside,
wherein the chip surface is a reflection-reduced chip surface having a reflectance <5%; and
at least one linear displacement sensor configured to detect a movement of the movable optics unit.

20. The miniaturized camera module as claimed in claim 19, wherein the at least one linear displacement sensor is magnetoresistive sensor.

21. (canceled)
